(19) United States
(12) Patent Application Publication
(10) Pub. No.: US 2024/0290670 A1
(43) Pub. Date: Aug. 29, 2024

(54) STEERED TRIM CUT

(71) Applicant: Texas Instruments Incorporated, Dallas, TX (US)

(72) Inventors: Joseph Yehle, Dallas, TX (US); Derek Young, Carrollton, TX (US); Roy Deidrick Solomon, Melissa, TX (US)

(21) Appl. No.: 18/175,267

(22) Filed: Feb. 27, 2023

(51) Int. Cl. H01L 21/66

(52) U.S. Cl. CPC H01L 22/34

(57) ABSTRACT

An electronic component includes a feature having opposite first and second sides spaced apart from one another along a first direction, third and fourth sides spaced apart from one another along an orthogonal second direction, and a cut extending in the feature. The cut has a first cut portion, a second cut portion and a final cut portion, the first cut portion extends from the third side toward the fourth side along the second direction, the second cut portion extends from the first cut portion partially toward the second side at a non-zero angle to the second direction, and the final cut portion extends partially toward the second or third side.

### BACKGROUND

Electronic components of an integrated circuit (IC) or other packaged electronic device can be trimmed during manufacturing to set a component value, mode or other performance metric of the component. Laser trimming creates a cut in a component feature, for example, to inhibit current flow and increase a component resistance from a starting value to a final value within a tolerance range of a desired final value. Straight single cut formation tends to saturate or lose control as the cut gets longer, and the final trimmed value accuracy depends on the ability to terminate trimming without overshooting. Adding additional trim cuts can enhance accuracy by allowing fine tuning, but this adds significate manufacturing cost due to extended trim time.

### SUMMARY

In one aspect, an electronic component includes first and second terminals and a feature having opposite first and second sides spaced along a first direction, third and fourth sides spaced along an orthogonal second direction, and a cut extending in the feature. The cut has a first cut portion, a second cut portion and a final cut portion. The first terminal is connected to a portion of the first side, the second terminal is connected to a portion of the second side, and the first cut portion extends from a first end along the third side toward the fourth side along the second direction. The second cut portion extends from the first cut portion partially toward the second side at a non-zero angle to the second direction, and the final cut portion extends partially toward one of the second and third sides.

In another aspect, a method includes forming a first cut portion in a feature of an electronic component, the feature having opposite first and second sides spaced apart from one another along a first direction, and third and fourth sides spaced apart from one another along an orthogonal second direction, and the first cut portion extending from a first end along the third side toward the fourth side along the second direction. The method also include forming a second cut portion extending from the first cut portion partially toward the second side at a non-zero angle to the second direction and forming a final cut portion extending partially toward one of the second and third sides.

In a further aspect, a system includes a cutting tool and a controller. The cutting tool is configured to remove material from a feature of an electronic component, the feature having opposite first and second sides spaced apart from one another along a first direction, and third and fourth sides spaced apart from one another along an orthogonal second direction. The controller is configured to control a position of the cutting tool to form a first cut portion extending from a first end along the third side toward the fourth side along the second direction, form a second cut portion extending from the first cut portion partially toward the second side at a non-zero angle to the second direction, and form a final cut portion extending partially toward one of the second and third sides.

### BRIEF DESCRIPTION OF THE DRAWINGS

FIG. 1 is a top perspective view of a semiconductor wafer with top side trimmable components in rows and columns of prospective semiconductor dies of unit areas and scribe streets.

FIG. 1A is a partial side view of a trimmable component with a trim cut in a unit of the semiconductor wafer.

FIG. 1B is a perspective view of a system with a packaged electronic device mounted to a circuit board and a trimmed circuit component of the circuit board.

FIG. 2 is a flow diagram of a method.

FIG. 3 is a simplified view of an electronic device manufacturing system.

FIGS. 3A-3G are partial top views of a trimmable component being laser trimmed.

FIGS. 4-8 are partial top views of trimmable components with further example trim cuts.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value and “substantially no” means zero or no measurable amount that reasonably affects quality or operation of a finished product or effectivity of a process. The example structures include layers or materials described as over or on another layer or material or surface, which can be a layer or material directly on and contacting the other layer or material or surface where other materials, such as impurities or artifacts or remnant materials from fabrication processing may be present between the layer or material and the other layer or material or surface.

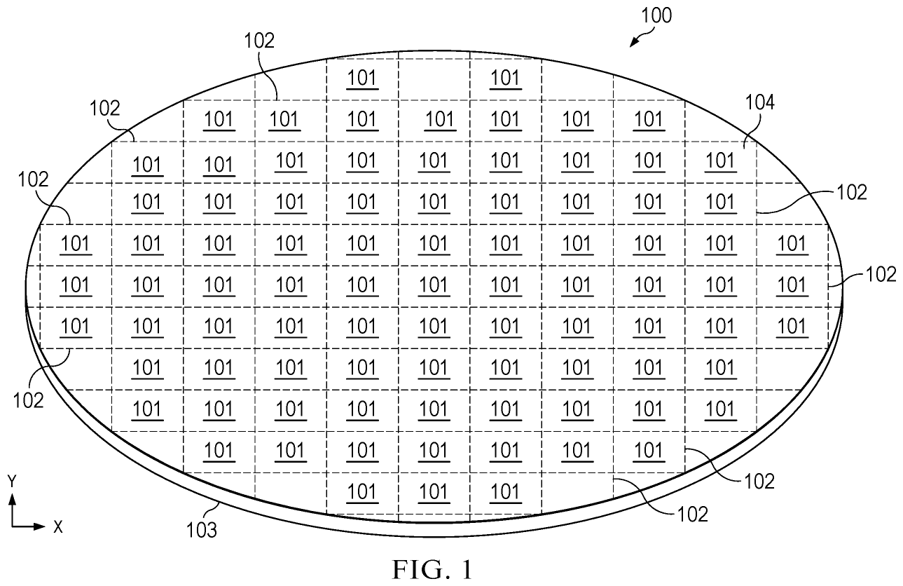

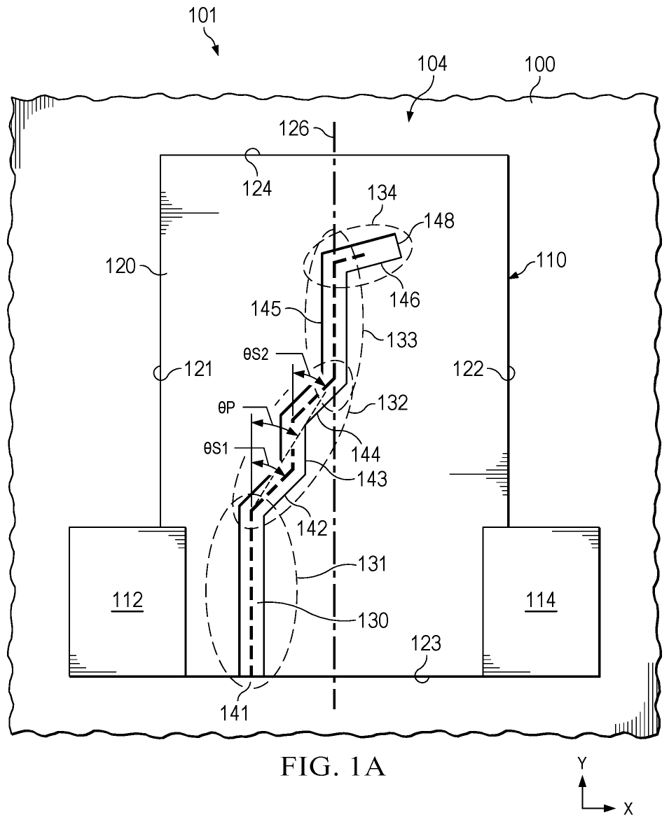

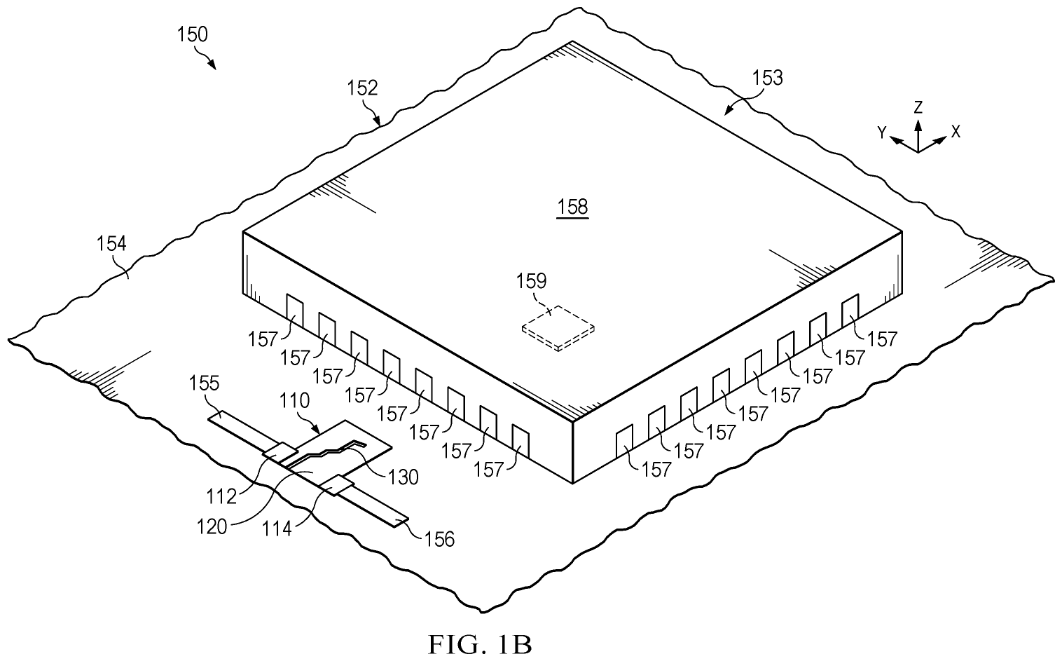

FIGS. 1 and 1A show an example semiconductor wafer 100 and FIG. 1B shows a packaged electronic device that includes a die of the wafer 100. The semiconductor wafer 100 is shown in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. As shown in FIG. 1, the semiconductor wafer 100 includes an array of unit areas 101 arranged in rows along the first direction X and columns along the second direction Y. The unit areas 101 are subsequently separated from the wafer 100 to form semiconductor dies. The semiconductor wafer 100 has respective scribe streets 102 between adjacent unit areas 101. As best shown in FIG. 1, the semiconductor wafer 100 has opposite first and second (e.g., bottom and top) sides 103 and 104, respectively, which are spaced apart from one another along the third direction Z. The top side 104 extends in a plane of the first and second directions X and Y. The semiconductor wafer 100 includes trimmable components in the unit areas 101 and scribe streets.

FIG. 1A shows a trimmable electronic component 110 in one unit area 101 along the top or second side 104 of the semiconductor wafer 100. Any type of trimmable electronic component can be trimmed. The illustrated example is a resistor component 110 with a conductive first terminal 112, a conductive second terminal 114 and a rectangular feature 120 that extends between the terminals 112 and 114. The feature 120 in one example is or includes a deposited film of silicon chromium (e.g., SiCr) of any suitable stoichiometry, thickness and dimensions. The feature 120 has a substantially rectangular shape with opposite respective first and second sides 121 and 122 that are spaced apart from one another along the first direction X, and opposite respective third and fourth sides 123 and 124 that are spaced apart from one another along the orthogonal second direction Y. A center line 126 of the rectangular feature 120 extends along the second direction Y approximately midway between the respective first and second sides 121 and 122 of the feature 120.

The feature 120 has a cut 130 that extends partially in the feature 120. The feature 120 is exposed along the top side 104 of the wafer 100 to allow a laser or other cutting tool to form the cut 130 therein to trim or otherwise adjust or set to the resistance of the resistor component 110 between the terminals 112 and 114. In the illustrated example, the cut 130 has a first cut portion 131, a second cut portion 132, a third cut portion 133, and a final cut portion 134. The cut 130 in this example has a beginning or first end 141 and includes segments 142, 143, 144, 145, and 146 extending to a second end 148. In another example, the third cut portion 133 can be omitted. The first terminal 112 is connected to a portion of the first side 121 and the second terminal 114 is connected to a portion of the second side 122 of the feature 120. In one implementation, the resistor component 110 is part of a circuit of the unit area 101 and the value of the resistance between the terminals 112 and 114 is trimmed during manufacturing to set or adjust one or more operational parameters of the circuit. In one implementation, the resistor component 110 is trimmed during wafer fabrication processing, for example, as part of wafer probe testing with a probe circuit actively monitoring (e.g., measuring) the component resistance during cutting operations to achieve a final component resistance value within a desired tolerance range.

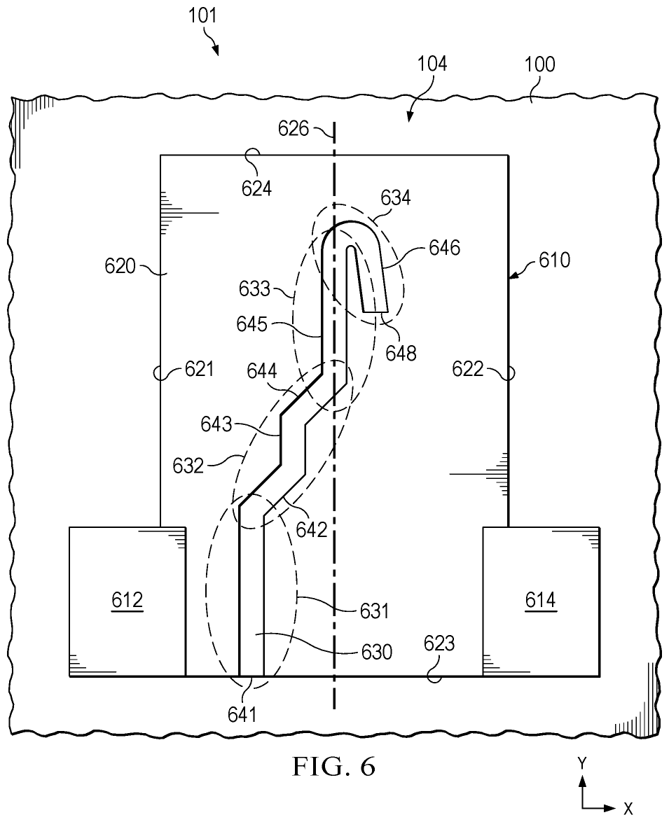

As shown in FIG. 1A, the first cut portion 131 extends from a first end 141 along the third side 123 at least partially toward the fourth side 124. In various implementations, the first cut portion 131 extends substantially along the second direction Y (e.g., within +/−10 degrees, such as within +/−2 degrees, preferably within +/−1 degree). In the illustrated example, the first cut portion 131 extends along the second direction Y. The second cut portion 132 extends from the first cut portion 131 at least partially toward the fourth side 124 and partially toward the second side 122 at a non-zero angle θP to the second direction Y. The second cut portion 132 includes multiple segments, with a segment 142 that extends at a non-zero first segment angle θS1 to the second direction Y, a segment 143 that extends along the second direction Y, and a segment 144 that extends at a non-zero second segment angle θS2 to the second direction Y. The third cut portion 133 extends from the second cut portion 132 toward the fourth side 124, at least partially along the second direction Y between the second cut portion 132 and the final cut portion 134. In the illustrated example, the first cut portion 131 extends along the second direction Y between the first side 121 and the center line 126 that is midway between the first and second sides 121 and 122 of the feature 120. In this example, moreover, the third cut portion 133 includes a single substantially straight segment 145 that extends at least partially along the center line 126 that is midway between the first and second sides 121 and 122 of the feature 120. The final cut portion 134 extends partially toward the second side 122. In another example (e.g., FIG. 6 below), the final cut portion 134 extends partially toward the third side 123.

FIG. 1B shows a partial perspective view of a system 150 that includes a printed circuit board (PCB) 152 and a packaged electronic device 153 mounted to a top side 154 of the PCB 152. The packaged electronic device 153 includes a semiconductor die 159 formed by a separated one of the unit areas 101 of the semiconductor wafer 100 of FIGS. 1 and 1A, as well as conductive leads 157 soldered to corresponding conductive pads (not shown) along the top side 154 of the PCB 152. The electronic device 153 in this example includes a molded plastic or ceramic package structure 158 that encloses at least a portion of the semiconductor die 159 and portions of the conductive leads 157. The semiconductor die 159 in this example includes an instance of the resistor electronic component 110 on a side (e.g., side 104) of the semiconductor die 159, where the component 110 has the above described feature 120 with a cut 130, and the first and second terminals 112 and 114 connected to a circuit of the semiconductor die 159 and/or to a circuit of the packaged electronic device 153. In one example, the top side 154 of the PCB 152 also includes an instance of the resistor electronic component 110 having the above described feature 120 with a cut 130, and the first and second terminals 112 and 114 connected to respective conductive traces 155 and 156 of the PCB 152. The described component trim cut 130 and associated trimming techniques and apparatus of the present disclosure find utility in trimmed or trimmable electronic components of one, some or all of a semiconductor wafer (e.g., wafer 100 of FIGS. 1 and 1A), an electronic device (e.g., the IC electronic device 153 of FIG. 1B) and/or a printed circuit board (e.g., the PCB 152 of FIG. 1B).

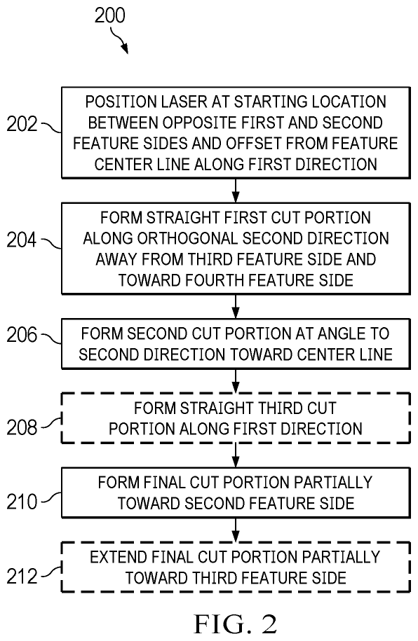

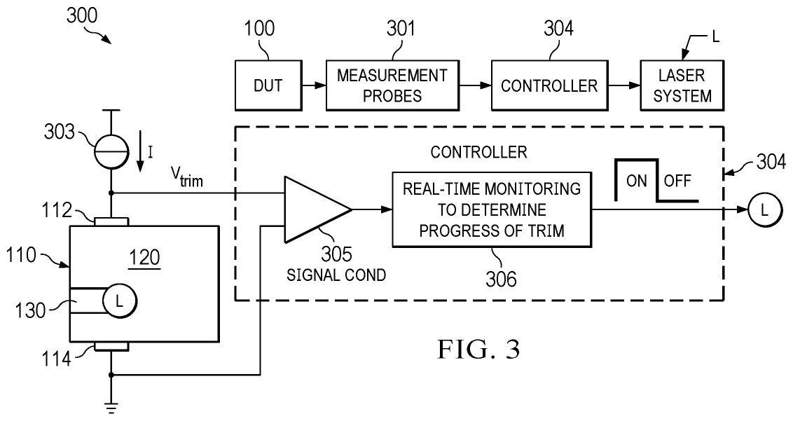

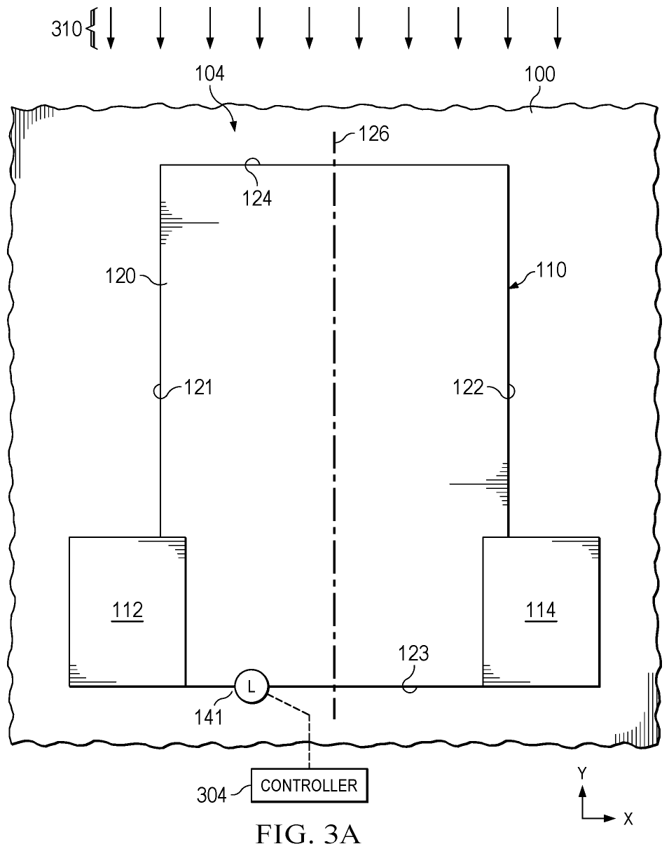

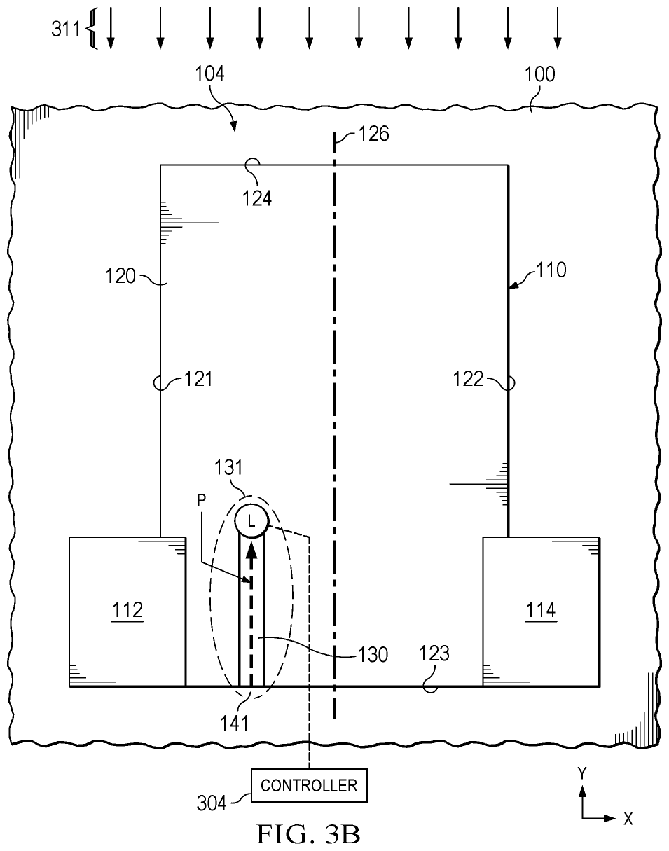

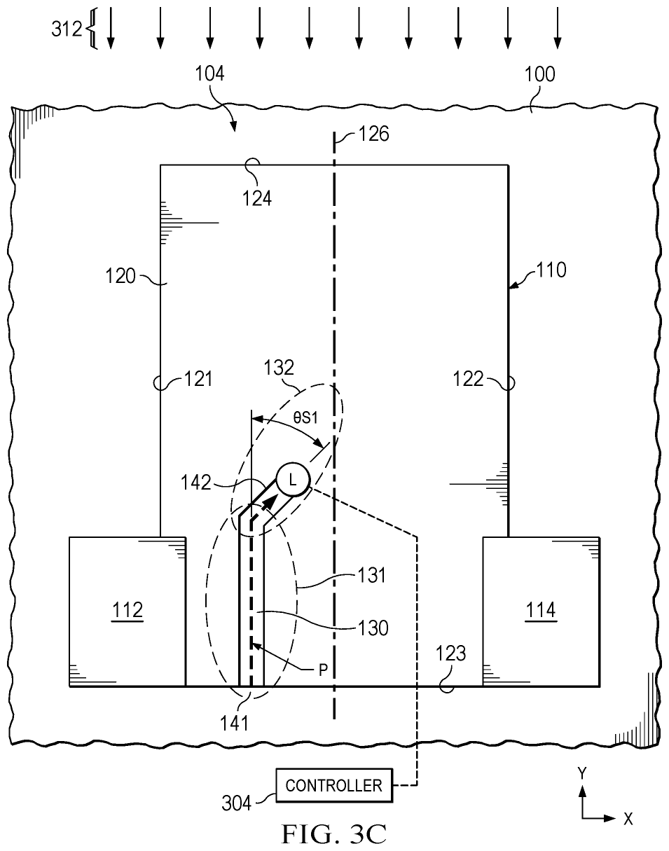

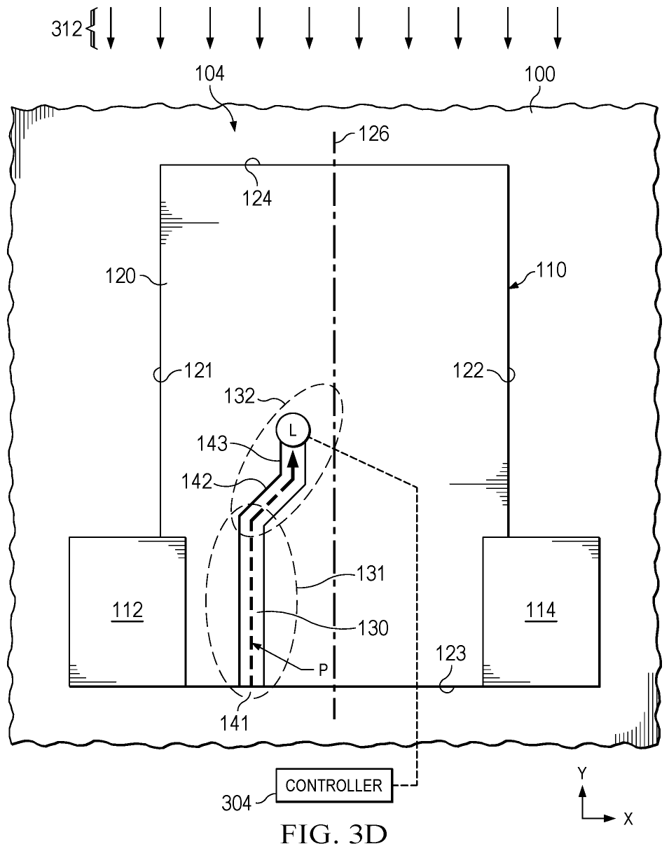

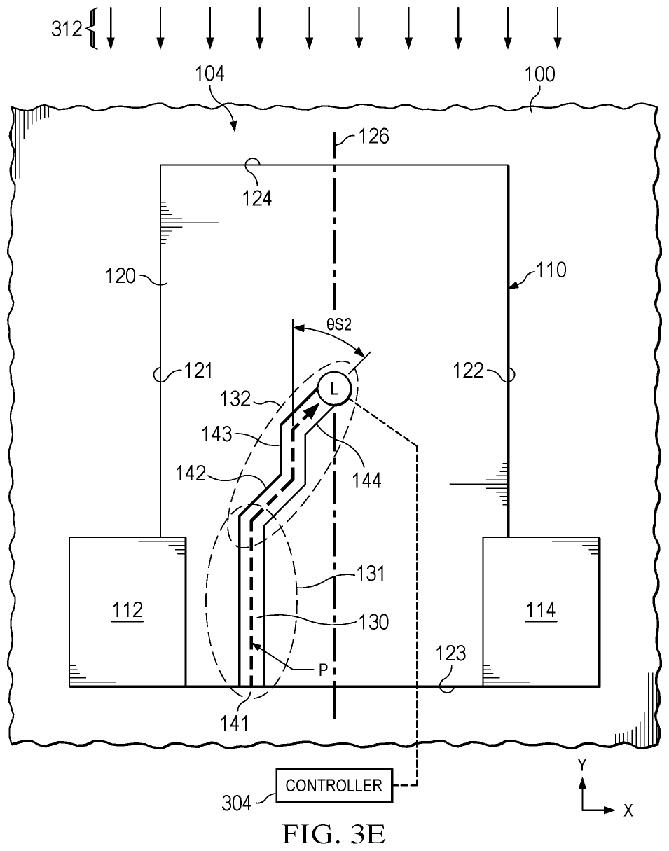

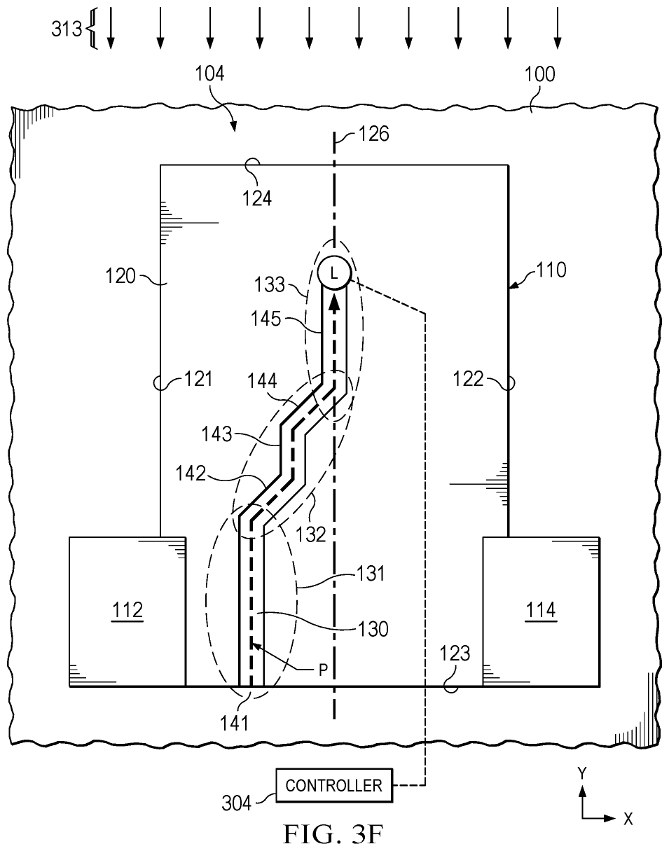

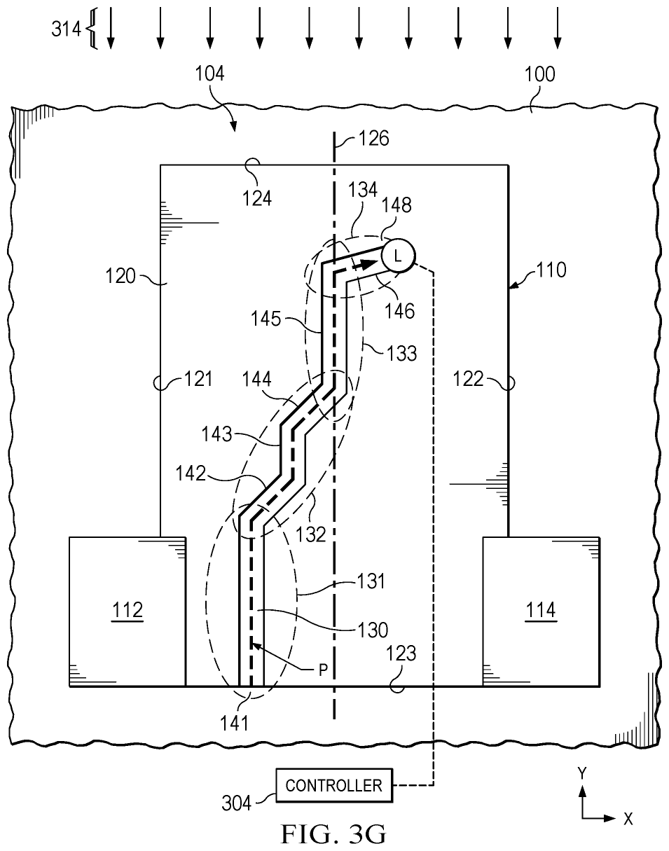

Referring also to FIGS. 2-3G, FIG. 2 shows a method 200 of fabricating an electronic component 110, with included trimming processing. The method 200 is illustrated in connection with FIGS. 3-3G in trimming a SiCr resistor component 110 of the wafer 100 by forming the cut 130 as described above using a laser cutting tool. The method 200 is implemented in one example in a system 300 illustrated in FIGS. 3-3G to form the trim cut 130 in a unit area 101 of the semiconductor wafer 100 prior to die separation and packaging. In other implementations, a cutting tool can be used to implement the method 200 to form a trim cut in a component feature on or in a separated or singulated semiconductor die (e.g., die 159 of FIG. 1B) after wafer singulation and prior to device packaging) and/or to trim form a trim cut in a component feature on or in of a PCB (e.g., PCB 152 of FIG. 1B).

In the illustrated example, a SiCr thin film resistor component 110 of the unit area 101 of wafer 100 has its resistance changed by forming the cut 130 while the resistance of the component 110 is measured by a sensing circuit in operation. The system 300 in FIG. 3 includes measurement probes 301, such as probe needles that contact copper pads, bumps, or other conductive features of the wafer 100 or other device under test (DUT), such as the semiconductor die 159 or PCB 152 of FIG. 1B. The probe card 301 in one example probes the terminals 112 and 114 of the electronic component 110 being trimmed and the measurement probes 301 are operatively coupled with a controller 304 to interface with a laser system L to create the trim cut 130. As further shown in FIG. 3, the system 300 has a current source circuit 303 configured to provide a current signal I to the first terminal 112 of the probed component 110. The second terminal 114 is coupled to a circuit ground reference by the measurement probes 301 as schematically shown in FIG. 3. The cut 130 forces the current I to take a longer path through the thin film of the feature 120 and increases the resistance of the component 110.

The controller 304 is configured to control the laser cutting tool L to remove material from the feature 120 and create the cut 130. The controller 304 is configured to control the position of the cutting tool L along the first and second directions X and Y in the illustrated orientation and to implement laser stop control to control the end of the cut 130 based on a measured component trim voltage signal Vₜᵣᵢₘ across the terminals 112 and 114 of the component 110 during trimming. The controller 304 provides a real-time feedback loop used to turn off the laser cutting tool L in response to the measured component trim voltage signal Vₜᵣᵢₘ exceeding a threshold while the current source 303 provides the current I to the component 110. The controller 304 in one example includes a signal conditioning circuit 305 that senses the component trim voltage signal Vₜᵣᵢₘ, and a real-time monitoring circuit 306 determines the progress of the trim cut 130 based on the output of the signal conditioning circuit 305 and controls the status (on or off) of the laser cutting tool L.

The laser cutting tool L in one example operates on a pulse by pulse basis with one voltage sample taken per Qrate period of the laser L. The operating Q-Rate is controlled by the controller 304 or set to a fixed rate in various implementations to set how fast the laser L fires, such as 100 Hz to 10 kHz, for example, approximately 1-2 kHz. A slower Q-rate setting allows more time for the trimmed component 110 of the DUT 100 to change behavior and for an active trim control loop to stabilize. In one example, the controller 304 sets or adjusts the laser Qrate to go as fast as is stable to facilitate reduced trimming time and manufacturing cost. The controller 304 determines whether to make the next pulse based on a most recent sample of the component trim voltage signal Vₜᵣᵢₘ and the output of the real-time monitoring circuit 306. The controller 304 in one example selectively adjusts the speed and separation of laser pulses to enhance precision in achieving a desired final component resistance. In these or other examples, the controller 304 controls laser pulse energy. In these or other examples, the controller 304 controls the bite size as the center to center spacing of subsequent pulses, for example, in a range of approximately 0.1 μm to 2.6 μm, such as approximately 0.2 μm to 2.0 μm, where smaller change per pulse facilitates finer resolution on the trim cut 130 and thus on the final component resistances for the resistor example 110 but involves a tradeoff in terms of increased trimming time and manufacturing cost. In one implementation, the controller 304 uses a bite size tailored to a desired resolution for a specific trim leg or portion. In these or other examples, the controller 304 controls speed and position of the cutting tool L along the first and second directions X and Y.

The method 200 includes positioning the cutting tool at a starting location (e.g., the beginning or prospective first end) 141 at 202 in FIG. 2. FIG. 3A shows one example, in which an initial tool placement or location process 310 is performed that positions the laser cutting tool L at the starting location 141 along the third side 123 of the component feature 120. Different types and forms of cutting tools can be used in other implementations. In the illustrated example, the starting location 141 is to the left of the center line 126 of the component feature 120.

At 204 in FIG. 2, the controller 304 controls the laser cutting tool L to form the first cut portion 131. FIG. 3B shows one example of a first portion cutting process 311, in which the controller 304 controls the laser cutting tool L to translate the laser cutting tool L along a path P approximately along the second direction Y from the starting location 141 toward the fourth side 124 of the component feature 120 to form the first cut portion 131 of the cut 130 extending from the first end 141 along the third side 123 toward the fourth side 124 along the second direction Y. In one example, the controller 304 uses a relatively high translation speed during translation of the laser cutting tool L to form the first cut portion 131 at 204.

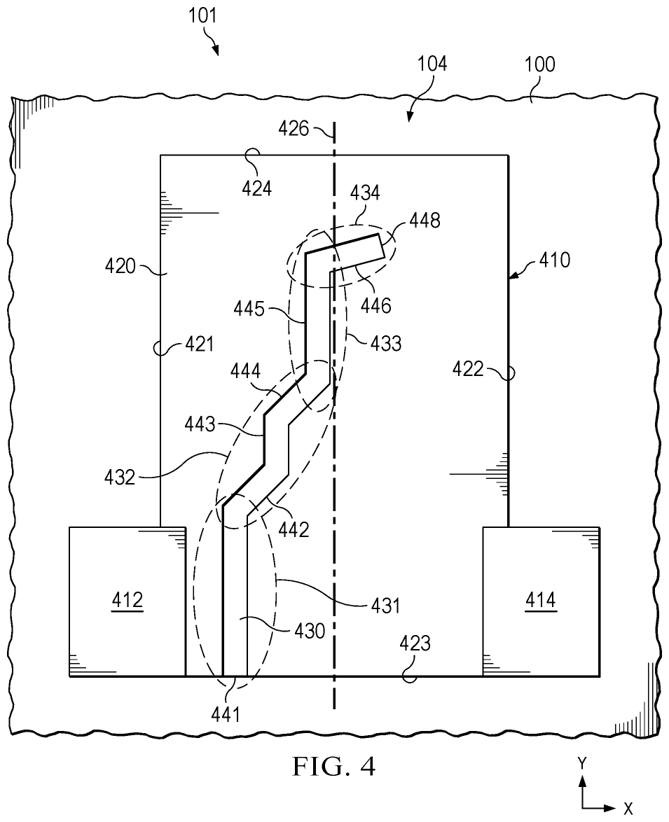

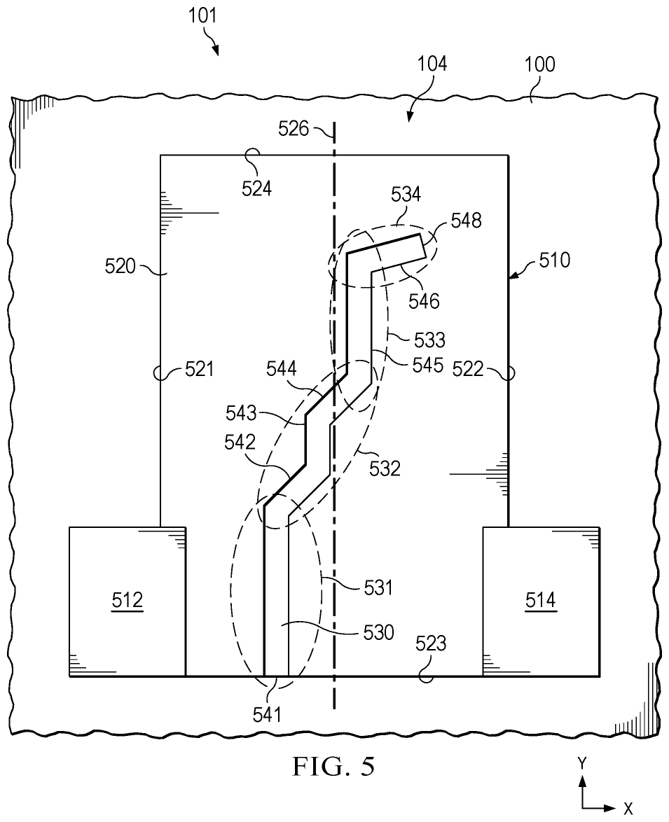

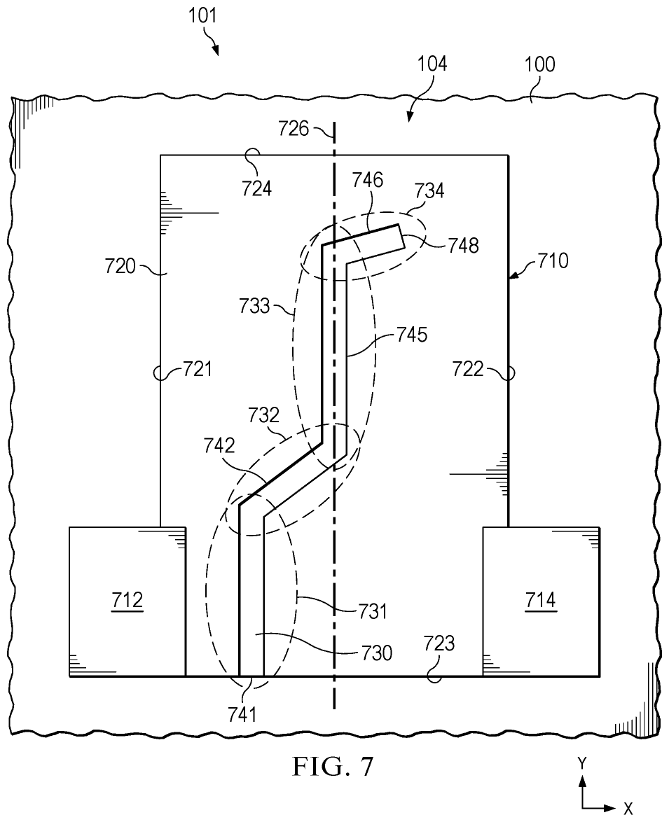

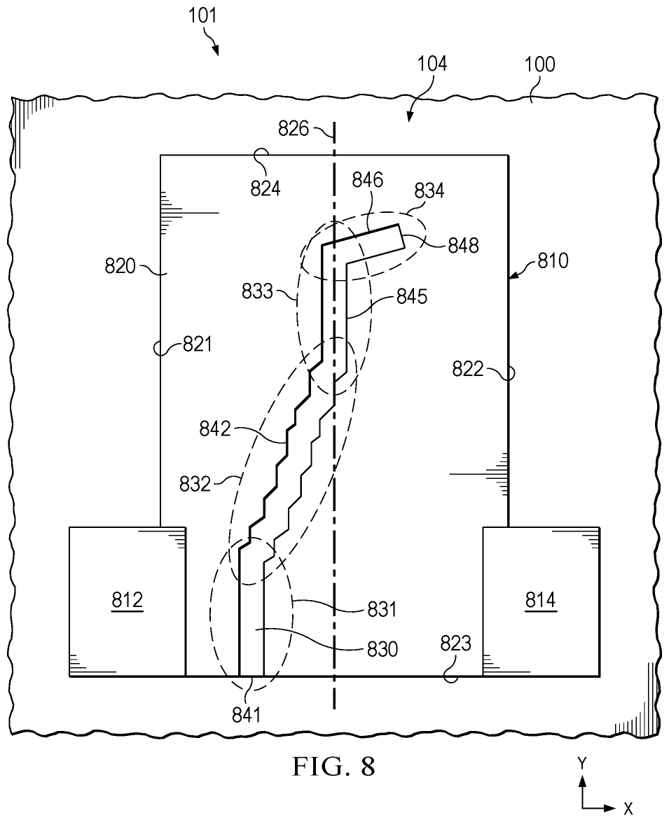

At 206 in FIG. 2, the controller 304 controls the laser cutting tool L to form the second cut portion 132. FIGS. 3C-3E show one example of a second portion cutting process 312, in which the controller 304 controls the laser cutting tool L to translate the laser cutting tool L at least partially toward the second side 122 to form the second cut portion 132. In the illustrated example, the second cut portion 132 includes multiple segments and the controller 304 controls the laser cutting tool L as shown in FIG. 3C to translate the laser cutting tool L at the non-zero first segment angle θS1 to the second direction Y to form the first segment 142 of the second cut portion 132. The second portion cutting process 312 in this example continues in FIG. 3D with the controller 304 controlling the laser cutting tool L to again translate approximately along the second direction Y to form the second segment 143 of the second cut portion 132. In FIG. 3E, the controller 304 controls the laser cutting tool L as shown in FIG. 3C to translate the laser cutting tool L at the non-zero second segment angle θS2 to the second direction Y to form the third segment 144 of the second cut portion 132. The third segment 144 in this example ends at least partially along the center line 126, although not a requirement of all possible implementations (e.g., see FIGS. 4 and 5 below). The illustrated second cut portion 132 in FIG. 3E has multiple angled segments 142 and 144 and one approximately vertical segment 143 and extends at the non-zero angle θP to the second direction Y. In other examples, the second cut portion can include a single angled segment extending at the non-zero angle θP to the second direction Y (e.g., FIG. 7 below) or the second cut portion 132 can include a higher number of angled segments (e.g., FIG. 8 below).

At 208 in FIG. 2, the controller 304 controls the cutting tool L to form the third cut portion 133. In other example, the third cut formation at 208 is omitted. FIG. 3F shows one example of a third portion cutting process 313, in which the controller 304 controls the laser cutting tool L to translate the laser cutting tool L at least partially along the second direction Y and at least partially along the center line 126 toward the fourth side 124 to form the third cut portion 133. The third cut portion 133 in this example includes a single segment 145 although not a requirement of all possible implementations. In one example, the controller 304 uses a slower translation speed during translation of the laser cutting tool L to form the third cut portion 133 at 208 than the translation speed used at 204 to form the first cut portion 131, although not a requirement of all possible implementations.

At 210 in FIG. 2, the method 200 includes forming the final cut portion 134. FIG. 3G shows one example of a final portion cutting process 314, in which the controller 304 controls the laser cutting tool L to translate the laser cutting tool L at least partially toward the second side 122 to form the final cut portion 134 having a single segment 146 with the final end 148. In another example, the controller 304 controls the laser cutting tool L at 212 in FIG. 2 to further translate the laser cutting tool L to extend the final cut portion 634 at least partially toward the third side 123 and with a single segment 646 and a final end 648, as shown in FIG. 6 below.

Referring also to FIGS. 4-8, FIG. 4 shows another example trimmable resistor component 410 with another example trim cut 430 in a unit area 101 along the top side 104 of the wafer 100. Other implementations can be formed on or in a separated semiconductor die and/or on or in a PCB (e.g., FIG. 1B above). In this example, the third cut portion 433 extends along the second direction Y between the first side 421 and a center line 426 that is midway between the first and second sides 421, 422 of the feature 420. FIG. 4 shows a trimmable component 410 in one unit area 101 along the top or second side 104 of the semiconductor wafer 100. Any type of trimmable electronic component can be trimmed. The illustrated trimmable component 410 is a resistor component 410 with a conductive first terminal 412, a conductive second terminal 414 and a rectangular feature 420 that extends between the terminals 412 and 414. The feature 420 in one example is or includes a deposited film of silicon chromium (e.g., SiCr) of any suitable stoichiometry, thickness and dimensions. The feature 420 has a substantially rectangular shape with opposite respective first and second sides 421 and 422 that are spaced apart from one another along the first direction X, and opposite respective third and fourth sides 423 and 424 that are spaced apart from one another along the orthogonal second direction Y. A center line 426 of the rectangular feature 420 extends along the second direction Y approximately midway between the respective first and second sides 421 and 422 of the feature 420.

The cut 430 extends partially in the feature 420 to set the resistance between the terminals 412 and 414, and includes a first cut portion 431, a second cut portion 432, a third cut portion 433, and a final cut portion 434. The cut 430 has a first end 441 and includes segments 442, 443, 444, 445, and 446 extending to a second end 448. In another example, the third cut portion 433 can be omitted. The first terminal 412 is connected to a portion of the first side 421 and the second terminal 414 is connected to a portion of the second side 422 of the feature 420. The first cut portion 431 extends from the first end 441 along the third side 423 at least partially toward the fourth side 424. In various implementations, the first cut portion 431 extends substantially along the second direction Y (e.g., within +/−10 degrees, such as within +/−2 degrees, preferably within +/−1 degree). In the illustrated example, the first cut portion 431 extends along the second direction Y. The second cut portion 432 extends from the first cut portion 431 at least partially toward the fourth side 424 and partially toward the second side 422 at a non-zero angle θP to the second direction Y. The second cut portion 432 includes multiple segments, with a segment 442 that extend at a non-zero first segment angle θS1 to the second direction Y, a segment 443 that extends along the second direction Y, and a segment 444 that extend at a non-zero second segment angle θS2 to the second direction Y. The third cut portion 433 extends from the second cut portion 432 toward the fourth side 424, at least partially along the second direction Y between the second cut portion 432 and the final cut portion 434. In the illustrated example, the first cut portion 431 extends along the second direction Y between the first side 421 and the center line 426. In this example, moreover, the third cut portion 433 includes a single substantially straight segment 445 that extends to the left of the center line 426, and the final cut portion 434 extends partially toward the second side 422 across the center line 426. In another example, the final cut portion 434 extends partially toward the third side 423.

FIG. 5 shows another example trimmable resistor component 510 with another example trim cut 530 in a unit area 101 along the top side 104 of the wafer 100. Other implementations can be formed in or in a separated semiconductor die and/or on or in a PCB (e.g., FIG. 1B above). In this example, the third cut portion 533 extends along the second direction Y between the center line 526 and the second side 522 of the component feature 520. FIG. 5 shows a trimmable component 510 in one unit area 101 along the top or second side 104 of the semiconductor wafer 100. Any type of trimmable electronic component can be trimmed. The illustrated trimmable component 510 is a resistor component 510 with a conductive first terminal 512, a conductive second terminal 514 and a rectangular feature 520 that extends between the terminals 512 and 514. The feature 520 in one example is or includes a deposited film of silicon chromium (e.g., SiCr) of any suitable stoichiometry, thickness and dimensions. The feature 520 has a substantially rectangular shape with opposite respective first and second sides 521 and 522 that are spaced apart from one another along the first direction X, and opposite respective third and fourth sides 523 and 524 that are spaced apart from one another along the orthogonal second direction Y. A center line 526 of the rectangular feature 520 extends along the second direction Y approximately midway between the respective first and second sides 521 and 522 of the feature 520.

The cut 530 extends partially in the feature 520 to set the resistance between the terminals 512 and 514, and includes a first cut portion 531, a second cut portion 532, a third cut portion 533, and a final cut portion 534. The cut 530 has a first end 541 and includes segments 542, 543, 544, 545, and 546 extending to a second end 548. In another example, the third cut portion 533 can be omitted. The first terminal 512 is connected to a portion of the first side 521 and the second terminal 514 is connected to a portion of the second side 522 of the feature 520. The first cut portion 531 extends from the first end 541 along the third side 523 at least partially toward the fourth side 524. In various implementations, the first cut portion 531 extends substantially along the second direction Y (e.g., within +/−10 degrees, such as within +/−2 degrees, preferably within +/−1 degree). In the illustrated example, the first cut portion 531 extends along the second direction Y. The second cut portion 532 extends from the first cut portion 531 at least partially toward the fourth side 524 and partially toward the second side 522 at a non-zero angle θP to the second direction Y. The second cut portion 532 includes multiple segments, with a segment 542 that extend at a non-zero first segment angle θS1 to the second direction Y, a segment 543 that extends along the second direction Y, and a segment 544 that extend at a non-zero second segment angle θS2 to the second direction Y. The third cut portion 533 extends from the second cut portion 532 toward the fourth side 524, at least partially along the second direction Y between the second cut portion 532 and the final cut portion 534. In the illustrated example, the first cut portion 531 extends along the second direction Y between the first side 521 and the center line 526. In this example, moreover, the third cut portion 533 includes a single substantially straight segment 545 that extends to the right of the center line 526, and the final cut portion 534 extends partially toward the second side 522 across the center line 526. In another example, the final cut portion 534 extends partially toward the third side 523.

FIG. 6 shows another example trimmable resistor component 610 with another example trim cut 630 in a unit area 101 along the top side 104 of the wafer 100. Other implementations can be formed on or in a separated semiconductor die and/or on or in a PCB (e.g., FIG. 1B above). In this example, the final cut portion 634 extends partially toward the third side 623. In this example, a trimmable component 610 extends in one unit area 101 along the top or second side 104 of the semiconductor wafer 100. Any type of trimmable electronic component can be trimmed. The illustrated trimmable component 610 is a resistor component 610 with a conductive first terminal 612, a conductive second terminal 614 and a rectangular feature 620 that extends between the terminals 612 and 614. The feature 620 in one example is or includes a deposited film of silicon chromium (e.g., SiCr) of any suitable stoichiometry, thickness and dimensions. The feature 620 has a substantially rectangular shape with opposite respective first and second sides 621 and 622 that are spaced apart from one another along the first direction X, and opposite respective third and fourth sides 623 and 624 that are spaced apart from one another along the orthogonal second direction Y. A center line 626 of the rectangular feature 620 extends along the second direction Y approximately midway between the respective first and second sides 621 and 622 of the feature 620, and the third cut portion 633 of the trim cut 630 extends at least partially along the center line 626.

The cut 630 extends partially in the feature 620 to set the resistance between the terminals 612 and 614, and includes a first cut portion 631, a second cut portion 632, a third cut portion 633, and a final cut portion 634. The cut 630 has a first end 641 and includes segments 642, 643, 644, 645, and 646 extending to a second end 648. In another example, the third cut portion 633 can be omitted. The first terminal 612 is connected to a portion of the first side 621 and the second terminal 614 is connected to a portion of the second side 622 of the feature 620. The first cut portion 631 extends from the first end 641 along the third side 623 at least partially toward the fourth side 624. In various implementations, the first cut portion 631 extends substantially along the second direction Y (e.g., within +/−10 degrees, such as within +/−2 degrees, preferably within +/−1 degree). In the illustrated example, the first cut portion 631 extends along the second direction Y. The second cut portion 632 extends from the first cut portion 631 at least partially toward the fourth side 624 and partially toward the second side 622 at a non-zero angle θP to the second direction Y. The second cut portion 632 includes multiple segments, with a segment 642 that extend at a non-zero first segment angle θS1 to the second direction Y, a segment 643 that extends along the second direction Y, and a segment 644 that extend at a non-zero second segment angle θS2 to the second direction Y. The third cut portion 633 extends from the second cut portion 632 toward the fourth side 624, at least partially along the second direction Y between the second cut portion 632 and the final cut portion 634 to the right of the center line 626. In the illustrated example, the first cut portion 631 extends along the second direction Y between the first side 621 and the center line 626. In this example, moreover, the final cut portion 634 extends partially toward the third side 623.

FIG. 7 shows yet another example trimmable resistor component 710 with another example trim cut 730 in a unit area 101 along the top side 104 of the wafer 100. Other implementations can be formed on or in a separated semiconductor die and/or on or in a PCB (e.g., FIG. 1B above). In this example, the second cut portion 732 of the trim cut 730 includes only a single segment 742 at an angle to the second direction Y. The trimmable component 710 in FIG. 7 extends in one unit area 101 along the top or second side 104 of the semiconductor wafer 100. Any type of trimmable electronic component can be trimmed. The illustrated trimmable component 710 is a resistor component 710 with a conductive first terminal 712, a conductive second terminal 714 and a rectangular feature 720 that extends between the terminals 712 and 714. The feature 720 in one example is or includes a deposited film of silicon chromium (e.g., SiCr) of any suitable stoichiometry, thickness and dimensions. The feature 720 has a substantially rectangular shape with opposite respective first and second sides 721 and 722 that are spaced apart from one another along the first direction X, and opposite respective third and fourth sides 723 and 724 that are spaced apart from one another along the orthogonal second direction Y. A center line 726 of the rectangular feature 720 extends along the second direction Y approximately midway between the respective first and second sides 721 and 722 of the feature 720, and the third cut portion 733 of the trim cut 730 extends at least partially along the center line 726.

The cut 730 extends partially in the feature 720 to set the resistance between the terminals 712 and 714, and includes a first cut portion 731, a second cut portion 732, a third cut portion 733, and a final cut portion 734. The cut 730 has a first end 741 and includes segments 742, 745, and 746 extending to a second end 748. In another example, the third cut portion 733 can be omitted. The first terminal 712 is connected to a portion of the first side 721 and the second terminal 714 is connected to a portion of the second side 722 of the feature 720. The first cut portion 731 extends from the first end 741 along the third side 723 at least partially toward the fourth side 724. In various implementations, the first cut portion 731 extends substantially along the second direction Y (e.g., within +/−10 degrees, such as within +/−2 degrees, preferably within +/−1 degree). In the illustrated example, the first cut portion 731 extends along the second direction Y. The second cut portion 732 extends from the first cut portion 731 at least partially toward the fourth side 724 and partially toward the second side 722 at a non-zero angle to the second direction Y. The second cut portion 732 include a single angled segment 742. The third cut portion 733 extends from the second cut portion 732 toward the fourth side 724, at least partially along the second direction Y between the second cut portion 732 and the final cut portion 734 along the center line 726. In the illustrated example, the first cut portion 731 extends along the second direction Y between the first side 721 and the center line 726. In this example, moreover, the third cut portion 733 includes a single substantially straight segment 745 that extends to the right of the center line 726, and the final cut portion 734 extends partially toward the second side 722. In another example, the final cut portion 734 extends partially toward the third side 723.

FIG. 8 shows yet another example trimmable resistor component 810 with another example trim cut 830 in a unit area 101 along the top side 104 of the wafer 100. Other implementations can be formed on or in a separated semiconductor die and/or on or in a PCB (e.g., FIG. 1B above). In this example, the second cut portion 832 of the trim cut 830 includes more than two angled segments 842 at respective angles to the second direction Y. The trimmable component 810 in FIG. 8 extends in one unit area 101 along the top or second side 104 of the semiconductor wafer 100. Any type of trimmable electronic component can be trimmed. The illustrated trimmable component 810 is a resistor component 810 with a conductive first terminal 812, a conductive second terminal 814 and a rectangular feature 820 that extends between the terminals 812 and 814. The feature 820 in one example is or includes a deposited film of silicon chromium (e.g., SiCr) of any suitable stoichiometry, thickness and dimensions. The feature 820 has a substantially rectangular shape with opposite respective first and second sides 821 and 822 that are spaced apart from one another along the first direction X, and opposite respective third and fourth sides 823 and 824 that are spaced apart from one another along the orthogonal second direction Y. A center line 826 of the rectangular feature 820 extends along the second direction Y approximately midway between the respective first and second sides 821 and 822 of the feature 820, and the third cut portion 833 of the trim cut 830 extends at least partially along the center line 826.

The cut 830 extends partially in the feature 820 to set the resistance between the terminals 812 and 814, and includes a first cut portion 831, a second cut portion 832, a third cut portion 833, and a final cut portion 834. The cut 830 has a first end 841 and includes segments 842, 845, and 846 extending to a second end 848. In another example, the third cut portion 833 can be omitted. The first terminal 812 is connected to a portion of the first side 821 and the second terminal 814 is connected to a portion of the second side 822 of the feature 820. The first cut portion 831 extends from the first end 841 along the third side 823 at least partially toward the fourth side 824. In various implementations, the first cut portion 831 extends substantially along the second direction Y (e.g., within +/−10 degrees, such as within +/−2 degrees, preferably within +/−1 degree). In the illustrated example, the first cut portion 831 extends along the second direction Y. The second cut portion 832 extends from the first cut portion 831 at least partially toward the fourth side 824 and partially toward the second side 822 at a non-zero angle to the second direction Y. The second cut portion 832 include a single angled segment 842. The third cut portion 833 extends from the second cut portion 832 toward the fourth side 824, at least partially along the second direction Y between the second cut portion 832 and the final cut portion 834 to the right of the center line 826. In the illustrated example, the first cut portion 831 extends along the second direction Y between the first side 821 and the center line 826. In this example, moreover, the third cut portion 833 includes a single substantially straight segment 845 that extends along the center line 826, and the final cut portion 834 extends partially toward the second side 822. In another example, the final cut portion 834 extends partially toward the third side 823.

Described examples facilitate enhanced trim cut accuracy with low cost and processing time by effectively linearizing the trim cutting response without using multiple feature cuts. Certain implementations create a more linear trim response from the start to finish for a single cut. The controller 304 steers the cut 130 towards the second side 122 in forming the second cut portion 132 to decrease the trim response for a small area and mitigate over-shooting, while keeping the total trim cutting time small to reduce manufacturing cost.

In certain examples, the single trim cut 130 is split into three regions, with the starting region offset to the first side 121 of the feature 120 to increase trim response, and the middle region includes forming the second cut portion 32 by dynamic steering, for example, to the center of the feature 120 to balance trim speed, resolution, and linearity of response. The end region in certain examples includes the final cut portion 134 cut by steering the cutting tool L toward the second feature side 122 to greatly reduce the resolution for high resolution end with reduced risk of over-shooting. The controller 304 can use real-time monitoring of the electrical change caused by every laser pulse and real-time monitoring of the rate of the electrical change.

Modifications are possible in the described examples, and other implementations are possible, within the scope of the claims.

What is claimed is:

1. An electronic component, comprising:
first and second terminals; and
a feature having opposite first and second sides spaced apart from one another along a first direction, third and fourth sides spaced apart from one another along an orthogonal second direction, and a cut extending in the feature and having a first cut portion, a second cut portion and a final cut portion, the first terminal connected to a portion of the first side, the second terminal connected to a portion of the second side, the first cut portion extending from a first end along the third side toward the fourth side substantially along the second direction, the second cut portion extending from the first cut portion partially toward the second side at a non-zero angle to the second direction, and the final cut portion extending partially toward one of the second and third sides.

2. The electronic component of claim 1, wherein the cut has a third cut portion extending along the second direction between the second cut portion and the final cut portion.

3. The electronic component of claim 2, wherein the third cut portion extends at least partially along a center line that is midway between the first and second sides of the feature.

4. The electronic component of claim 2, wherein the third cut portion extends along the second direction between the first side and a center line that is midway between the first and second sides of the feature.

5. The electronic component of claim 2, wherein the third cut portion extends along the second direction between the second side and a center line that is midway between the first and second sides of the feature.

6. The electronic component of claim 1, wherein the second cut portion includes multiple segments that extend at a non-zero segment angle to the second direction.

7. The electronic component of claim 1, wherein the first cut portion extends along the second direction between the first side and a center line that is midway between the first and second sides of the feature.

8. The electronic component of claim 1, wherein the electronic component extends on or in a semiconductor wafer.

9. The electronic component of claim 1, wherein the electronic component extends on or in a semiconductor die.

10. The electronic component of claim 1, wherein the electronic component extends on or in a circuit board.

11. A method of fabricating an electronic component, the method comprising:
forming a first cut portion in a feature of the electronic component, the feature having opposite first and second sides spaced apart from one another along a first direction, and third and fourth sides spaced apart from one another along an orthogonal second direction, and the first cut portion extending from a first end along the third side toward the fourth side substantially along the second direction;
forming a second cut portion extending from the first cut portion partially toward the second side at a non-zero angle to the second direction; and
forming a final cut portion extending partially toward one of the second and third sides.

12. The method of claim 11, further comprising forming a third cut portion that extends along the second direction between the second cut portion and the final cut portion.

13. The method of claim 12, comprising forming the third cut portion at least partially along a center line that is midway between the first and second sides of the feature.

14. The method of claim 12, comprising forming the third cut portion along the second direction between the first side and a center line that is midway between the first and second sides of the feature.

15. The method of claim 12, comprising forming the third cut portion along the second direction between the second side and a center line that is midway between the first and second sides of the feature.

16. The method of claim 11, comprising forming the second cut portion including multiple segments that extend at a non-zero segment angle to the second direction.

17. The method of claim 11, comprising forming the first cut portion along the second direction between the first side and a center line that is midway between the first and second sides of the feature.

18. The method of claim 11, wherein the electronic component extends on or in one of a semiconductor wafer, a semiconductor die, and a circuit board.

19. A system for fabricating an electronic component, the system comprising:
a cutting tool configured to remove material from a feature of an electronic component, the feature having opposite first and second sides spaced apart from one another along a first direction, and third and fourth sides spaced apart from one another along an orthogonal second direction; and
a controller configured to control a position of the cutting tool to:
form a first cut portion extending from a first end along the third side toward the fourth side substantially along the second direction;
form a second cut portion extending from the first cut portion partially toward the second side at a non-zero angle to the second direction; and
form a final cut portion extending partially toward one of the second and third sides.

20. The system of claim 19, wherein the controller is configured to control the position of the cutting tool to form a third cut portion that extends along the second direction between the second cut portion and the final cut portion.
